(19) United States
(12) Patent Application Publication
(10) Pub. No.: US 2026/0194806 A1
(43) Pub. Date: Jul. 9, 2026

(54) PHOTOMASK, METHOD OF FORMING PATTERN USING THE SAME, METHOD OF MANUFACTURING DISPLAY DEVICE USING THE SAME AND ELECTRONIC DEVICE INCLUDING DISPLAY DEVICE

(71) Applicant: Samsung Display Co., LTD., Yongin-si (KR)

(72) Inventor: Jae Woo LEE, Yongin-si (KR)

(21) Appl. No.: 19/345,537

(22) Filed: Sep. 30, 2025

(30) Foreign Application Priority Data
Jan. 6, 2025 (KR) 10-2025-0001662

(51) Int. Cl. G03F 1/60; G03F 1/80; H10K 59/12; H10K 71/60

(52) U.S. Cl. CPC G03F 1/60; G03F 1/80; H10K 59/1201; H10K 71/60

(57) ABSTRACT

A photomask includes a transparent substrate having a first surface and a second surface, which are opposite to each other, a first translucent layer disposed on the first surface of the transparent substrate, a light-shielding layer disposed on the second surface of the transparent substrate, and a second translucent layer disposed between the second surface of the transparent substrate and the light-shielding layer. The second translucent layer has a higher transmittance than a transmittance of the first translucent layer.

This application claims priority to Korean Patent Application No. 10-2025-0001662, filed on Jan. 6, 2025, and all the benefits accruing therefrom under 35 U.S.C. § 119, the content of which in its entirety is herein incorporated by reference herein.

### BACKGROUND

### (1) Field

Embodiments of the present disclosure relate to a photomask, a method of forming a pattern using the photomask, a method of manufacturing a display device using the photomask and an electronic device including the display device. More particularly, embodiments of the present disclosure relate to a photomask including a light-shielding layer and a functional layer, a method of forming a pattern using the photomask, a method of manufacturing a display device using the photomask, and an electronic device including the display device.

### (2) Description of the Related Art

In a display device such as an organic light-emitting diode (OLED) display device and a liquid crystal display (LCD) device, a display substrate including thin film transistors (TFT) and various wirings may be provided, and a display structure including electrodes and emission layers may be formed on the display substrate.

To form the TFT, the wirings and the electrodes, a photo-lithography process using a photomask may be used. Recently, a photomask and an exposure process using the photomask for stably implementing a high-resolution display device have been researched.

### SUMMARY

According to an embodiment of the present disclosure, there is provided a photomask having improved exposure and optical properties.

According to an embodiment of the present disclosure, there is provided a method of forming a pattern using the photomask.

According to an embodiment of the present disclosure, there is provided a method of manufacturing a display device using the photomask.

According to an embodiment of the present disclosure, there is provided an electronic device including the display device.

According to an embodiment of the present disclosure, a photomask includes a transparent substrate having a first surface and a second surface, which are opposite to each other, a first translucent layer disposed on the first surface of the transparent substrate, a light-shielding layer disposed on the second surface of the transparent substrate, and a second translucent layer disposed between the second surface of the transparent substrate and the light-shielding layer. In such an embodiment, the second translucent layer has a higher transmittance than a transmittance of the first translucent layer.

In some embodiments, the first translucent layer may have a higher reflectance than a reflectance of the second translucent layer.

In some embodiments, each of the first translucent layer and the second translucent layer may include a metal, a metal oxide, or an organic material.

In some embodiments, the light-shielding layer may include a first metal, and the first translucent layer or the second translucent layer may include a second metal different from the first metal.

In some embodiments, the first metal may include chromium (Cr) or molybdenum (Mo), and the second metal may include aluminum (Al), silver (Ag), copper (Cu), or tungsten (W).

In some embodiments, the second metal may include aluminum (Al) or silver (Ag).

In some embodiments, the first translucent layer may include the metal or the metal oxide, and the second translucent layer may include the organic material.

In some embodiments, a thickness of the first translucent layer may be greater than a thickness of the second translucent layer.

In some embodiments, the thickness of the first translucent layer may be in a range from about 5 nanometers (nm) to about 20 nm, and the thickness of the second translucent layer may be in a range from about 1 nm to about 10 nm.

In some embodiments, the first translucent layer and the second translucent layer may include the same metal as each other.

In some embodiments, a thickness of each of the first translucent layer and the second translucent layer may be less than a thickness of the light-shielding layer.

In some embodiments, an opening, may be defined through the light-shielding layer, and the second translucent layer may be exposed through the opening.

According to an embodiment of the present disclosure, a method for forming a pattern includes forming an etching target layer on a substrate, forming a photoresist layer on the etching target layer, arranging a photomask on the photoresist layer, forming a photoresist pattern by partially removing the photoresist layer by an exposure process using the photomask and a development process, ad partially etching the etching target layer using the photoresist pattern In such an embodiment, the photomask includes a transparent substrate having a first surface and a second surface, which are opposite to each other, a first translucent layer disposed on the first surface of the transparent substrate, a light-shielding layer disposed on the second surface of the transparent substrate, and a second translucent layer disposed between the second surface of the transparent substrate and the light-shielding layer. In such an embodiment, the second translucent layer has a higher transmittance than a transmittance of the first translucent layer.

In some embodiments, the exposure process using the photomask may be performed by generating a constructive interference or an optical resonance of a light radiated from a light source between the first translucent layer and the second translucent layer of the photomask.

In some embodiments, the constructive interference or the optical resonance may be generated by repeatedly generating a partial reflected light of light radiated from the light source by the second translucent layer and a re-reflected light by the first translucent layer.

According to an embodiment of the present disclosure, a method of manufacturing a display device includes forming a transistor including an active layer on a substrate, forming an insulating interlayer covering the transistor, forming a contact electrode penetrating the insulating interlayer and electrically connected to the active layer, forming a via insulation layer covering the contact electrode on the insulating interlayer, forming a via electrode penetrating the via insulation layer and electrically connected to the contact electrode, forming a light-emitting device electrically connected to the transistor through the via electrode or the contact electrode. In such an embodiment, the forming the contact electrode or the forming the via electrode include performing a photo-lithography process using a photomask may be performed. In such an embodiment, the photomask includes a transparent substrate having a first surface and a second surface, which are opposite to each other, a first translucent layer disposed on the first surface of the transparent substrate, a light-shielding layer disposed on the second surface of the transparent substrate, and a second translucent layer disposed between the second surface of the transparent substrate and the light-shielding layer. In such an embodiment, the second translucent layer has a higher transmittance than a transmittance of the first translucent layer.

In some embodiments, of the forming the contact electrode may include forming a photoresist layer on the insulating interlayer, arranging the photomask on the photoresist layer, forming a photoresist pattern including a first etching hole may by partially removing the photoresist layer by an exposure process using the photomask and a development process, partially etching the insulating interlayer using the first etching hole of the photoresist pattern to form a contact hole exposing a portion of the active layer, and forming a conductive layer filling the contact hole.

In some embodiments, the forming the via electrode may include forming photoresist layer on the via insulation layer, arranging the photomask on the photoresist layer, forming a photoresist pattern including a second etching hole by partially removing the photoresist layer by an exposure process using the photomask and a development process, partially etching the via insulation layer using the second etching hole of the photoresist pattern to form a via hole exposing a portion of the contact electrode, and forming a conductive layer filling the via hole may be formed.

According to an embodiment of the present disclosure, an electronic device includes the display device manufactured by the above-described method, a memory, and a processor which executes data included in the memory to control an operation of the display device.

In some embodiments, the electronic device may include virtual reality or augmented reality glasses, a smartphone, a tablet personal computer (PC), a laptop computer, a television (TV), a desk monitor, smart glasses, a head-mounted display, a smart watch, or a vehicle display.

The photomask according to embodiments may include first and second translucent layers having different transmittances or reflectances from each other. In such embodiments, light intensity and concentration in an exposure process may be improved by a resonance effect between the first and second translucent layers.

Thus, excessive slope formation of a photoresist may be effectively prevented, and a fine-dimensional pattern may be effectively formed.

### BRIEF DESCRIPTION OF THE DRAWINGS

FIG. 1 is a schematic cross-sectional view illustrating a photomask according to embodiments.

FIG. 2 is a schematic cross-sectional view for describing a pattern formation using a photomask of a comparative example.

FIGS. 3 to 6 are schematic cross-sectional views illustrating a method of forming a pattern according to embodiments.

FIGS. 7 to 16 are schematic cross-sectional views illustrating a method of manufacturing a display device according to embodiments.

FIGS. 17A and 17B are schematic cross-sectional views illustrating light-emitting devices included in a display device according to embodiments.

FIG. 18 is an exploded perspective view of an electronic device according to embodiments.

FIG. 19 is a block diagram of an electronic device according to an embodiment.

FIG. 20 is a schematic diagrams of electronic devices according to embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

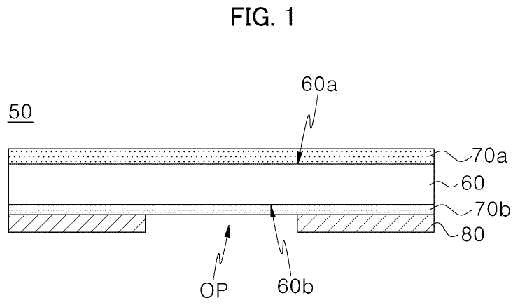

FIG. 1 is a schematic cross-sectional view illustrating a photomask according to embodiments.

Referring to FIG. 1, an embodiment of a photomask 50 may include a transparent substrate 60 and a light-shielding layer 80. According to embodiments of the present disclosure, the photomask 50 may further include a first translucent layer (a first semi-transmissive layer) 70a and a second translucent layer (a second semi-transmissive layer) 70b.

The transparent substrate 60 may have the highest transmittance (e.g., a transmittance with respect to of an ultraviolet light used in an exposure process) among components or layers included in the photomask 50. The transparent substrate 60 may substantially transmit a light and may not change a phase of the light transmitting therethrough. According to embodiments, the transparent substrate 60 may be a quartz substrate.

The transparent substrate 60 may have a first surface 60a and a second surface 60b. The first surface 60a and the second surface 60b may be opposite to each other. In an embodiment, as shown in the cross-section of FIG. 1, the first surface 60a and the second surface 60b may correspond to a top surface and a bottom surface of the transparent substrate 60, respectively.

The first surface 60a may be a surface facing a light source LS (see FIG. 4) in the exposure process. The second surface 60b may be a surface facing a photoresist layer in the exposure process.

The light-shielding layer 80 may be disposed on the second surface 60b of the transparent substrate 60. The light-shielding layer 80 may include an opening OP formed therethrough. The light-shielding layer 80 may be provided with an opening OP, i.e., the opening OP is defined through the light-shielding layer 80. A light from the light source LS may be radiated to the photoresist layer through the opening OP to perform an exposure process. A light radiated to the light-shielding layer 80 may be substantially blocked.

In an embodiment, for example, the light-shielding layer 80 may include a metal (a first metal) including chromium (Cr) and/or molybdenum (Mo), an alloy, an oxide thereof, a nitride thereof, or an oxynitride thereof.

In some embodiments, a thickness of the light-shielding layer 80 may be in a range from about 50 nanometers (nm) to about 300 nm, or from about 100 nm to about 200 nm.

In an embodiment, the opening OP may have a hole shape included in the light shielding layer 80. In an embodiment, the light-shielding layer 80 may include a plurality of light-shielding patterns physically separated from each other. In such an embodiment, the opening OP may have a trench shape formed between adjacent light-shielding patterns.

The first translucent layer 70a may be disposed on the first surface 60a of the transparent substrate 60. The second translucent layer 70b may be disposed on the second surface 60b of the transparent substrate 60. The first translucent layer 70a may be in direct contact with the first surface 60a of the transparent substrate 60. The second translucent layer 70b may be in direct contact with the second surface 60b of the transparent substrate 60.

The term “translucent layer” used herein comprehensively refers to a layer having a transmittance less than that of the transparent substrate 60 and greater than that of the light-shielding layer 80.

The second translucent layer 70b may be disposed between the transparent substrate 60 and the light-shielding layer 80. A surface of the second translucent layer 70b may be partially exposed by the opening OP.

According to embodiments, a transmittance (e.g., a transmittance with respect to the light from the light source LS) of the first translucent layer 70a may be less than that of the second translucent layer 70b. In some embodiments, a reflectance of the first translucent layer 70a may be greater than that of the second translucent layer 70b.

According to embodiments, the reflectance of each of the first translucent layer 70a and the second translucent layer 70b may be less than that of the light-shielding layer 80.

Materials and thicknesses of the first translucent layer 70a and the second translucent layer 70b may be selected and adjusted within a range satisfying the above-described transmittance or reflectance relationship.

According to embodiments, the first translucent layer 70a and the second translucent layer 70b may include at least one selected from a metal, a metal oxide or an organic material.

In some embodiments, the metal or the metal oxide included in the first translucent layer 70a and the second translucent layer 70b may contain a second metal different from the first metal included in the light-shielding layer 80. In an embodiment, for example, the second metal may include at least one selected from aluminum (Al), silver (Ag), copper (Cu) and/or tungsten (W). In an embodiment, the second metal may include at least one selected from aluminum (Al) and/or silver (Ag).

The organic materials may include a polyester-based resin such as polyethylene terephthalate, polyethylene isophthalate, polyethylene naphthalate and polybutylene terephthalate; a cellulose-based resin such as diacetyl cellulose and triacetyl cellulose; a polycarbonate-based resin; an acrylic resin such as polymethyl (meth)acrylate and polyethyl (meth)acrylate; a styrene-based resin such as polystyrene and an acrylonitrile-styrene copolymer; a polyolefin-based resin such as polyethylene, polypropylene, a cycloolefin or polyolefin having a norbornene structure and an ethylene-propylene copolymer; a vinyl chloride-based resin; an amide-based resin such as nylon and an aromatic polyamide; an imide-based resin; a polyethersulfone-based resin; a sulfone-based resin; a polyether ether ketone-based resin; a polyphenylene sulfide resin; a vinyl alcohol-based resin; a vinylidene chloride-based resin; a vinyl butyral-based resin; an allylate-based resin; a polyoxymethylene-based resin; an epoxy-based resin; a urethane or acrylic urethane-based resin; a silicone-based resin, etc. These may be used alone or in a combination of two or more therefrom.

In some embodiments, the first translucent layer 70a may include the metal or the metal oxide, and the second translucent layer 70b may include the organic material. In such embodiments, a thickness of the second translucent layer 70b may be greater than a thickness of the first translucent layer 70a. In an embodiment, for example, the thickness of the second translucent layer 70b including the organic material may be increased, so that the second translucent layer 70b may be adjusted to have a transmittance greater than that of the first translucent layer 70a and less than that of the transparent substrate 60.

In some embodiments, each of the first translucent layer 70a and the second translucent layer 70b may be a metal layer including the second metal or a metal oxide layer including the second metal. In such embodiments, the thickness of the first translucent layer 70a may be greater than the thickness of the second translucent layer 70b.

In an embodiment, for example, the thickness of the first translucent layer 70 a may be in a range from about 5 nm to about 20 nm, from about 5 nm to about 15 nm, or from about 5 nm to 10 nm. In an embodiment, for example, the thickness of the second translucent layer 70 b may be in a range from 1 nm to about 10 nm, from about 2 nm to about 8 nm, or from about 2 nm to about 6 nm.

In such embodiments, as described above, even when the first translucent layer 70a and the second translucent layer 70b include a same material, e.g., a same metal, as each other, the thickness of the first translucent layer 70a may be relatively increased to increase the reflectance in the first translucent layer 70a relatively to that in the second translucent layer 70b.

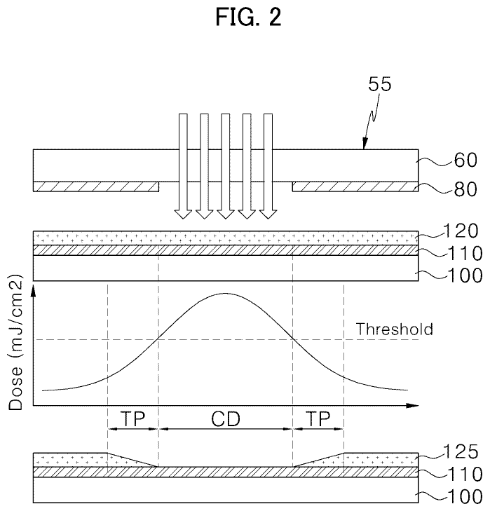

FIG. 2 is a schematic cross-sectional view for describing a pattern formation using a photomask of a comparative example.

Referring to FIG. 2, a photomask 55 of a comparative example includes a transparent substrate 60 and a light-shielding layer 80 formed on one surface of the transparent substrate 60 (e.g., the second surface 60b of FIG. 1) and the first and second translucent layers 70a and 70b of FIG. 1 are omitted.

A photo-lithography process may be performed using the photomask 55 of the comparative example. As illustrated in FIG. 2, an etching target layer 110 may be formed on the substrate 100, and a photoresist layer 120 may be formed on the etching target layer 110.

The photomask 55 may be aligned in a way such that the light-shielding layer 80 faces over the photoresist layer 120. Thereafter, a light may be radiated onto the photoresist layer 120 through an opening included or defined in the light-shielding layer 80 as indicated by arrows. A photoresist pattern 125 may be formed by removing an exposed portion of the photoresist layer 120 by a developing process.

For example, a portion of the photoresist layer 120, to which a light energy beyond a threshold energy is radiated, may be dissolved in a developer solution by a chemical transformation, and removed.

According to a comparative example, the light energy (dose: mJ/cm²) passing through the photomask 55 may be distributed in both lateral directions from a center according to, e.g., a Gaussian distribution.

For example, the light energy may be dispersed to both lateral sides of an area corresponding to a desired target critical dimension CD. Accordingly, the light energy may be applied to the photoresist layer 120 to an outside of the target critical dimension CD to be partially removed by the developing process.

Thus, an inclined portion TP is formed in a non-exposed portion of the photoresist layer 120 adjacent to the exposed portion. As the Gaussian distribution become wide, a length of the inclined portion TP increases, and a slope of the inclined portion TP may be reduced.

Accordingly, a pattern having a desired resolution, pitch or line and space (L/S) may not be obtained from the etching target layer 110 by a subsequent etching process using the photoresist pattern 125 as an etching mask.

For example, formation of a via hole or a contact hole having a narrow line width and a high aspect ratio may not be effectively implemented with the desired resolution and reliability from the photomask 55 in the comparative example.

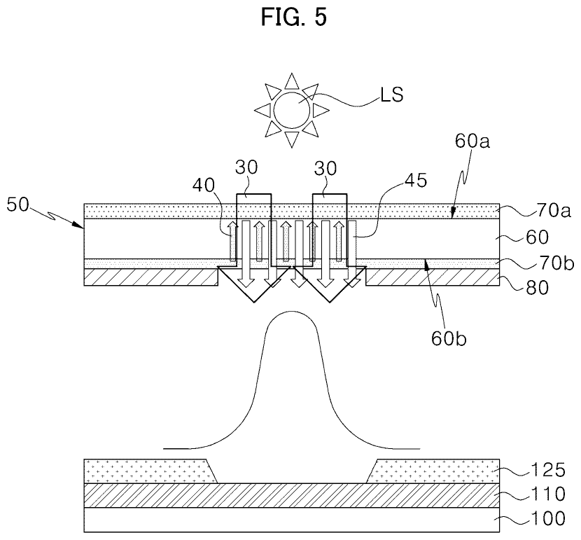

However, as described later with reference to, e.g., FIG. 5, the photomask 50 according to embodiments described with reference to FIG. 1 may be used to suppress the dispersion of light radiated during the exposure process and obtain a narrow Gaussian distribution by a resonance effect between the translucent layers 70a and 70b.

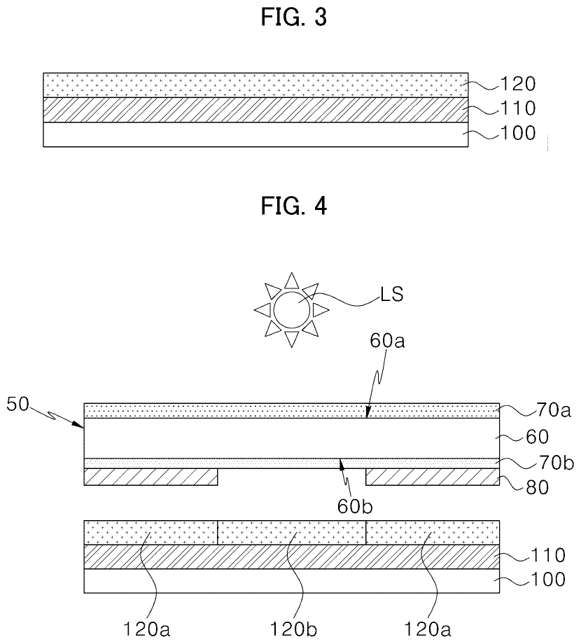

FIGS. 3 to 6 are schematic cross-sectional views illustrating a method of forming a pattern according to embodiments.

Referring to FIG. 3, in an embodiment of a method of forming a pattern, an etching target layer 110 may be formed on a substrate 100. A photoresist layer 120 may be formed on the etching target layer 110.

The substrate 100 may include a semiconductor substrate, a glass substrate, or a polymer substrate. According to embodiments, the substrate 100 may be provided as a support substrate or a back-plane substrate of a display device.

In some embodiments, the substrate 100 may include a polymer material having transparency and flexibility. In such an embodiment, the substrate 100 may be used in a transparent flexible display device. In an embodiment, for example, the substrate 100 may include a polymer material such as polyimide, polysiloxane, an epoxy resin, an acrylic resin, polyester, or the like. In an embodiment, the substrate 100 may include polyimide.

The etching target layer 110 may refer to a layer to be partially removed or patterned by a photo-lithography process using the photomask 50 and the photoresist layer 120.

The etching target layer 110 may include at least one selected from: an inorganic insulating material such as silicon oxide, silicon nitride, silicon oxynitride, a metal oxide, a metal nitride, a metal oxynitride, or the like; an organic insulating material such as an epoxy resin, a siloxane resin, an acrylic resin, an imide-based resin, or the like; a metal or a conductive material such as a transparent conductive oxide (e.g., indium tin oxide (ITO), indium zinc oxide (IZO), or the like; and a semiconductor material such as an oxide semiconductor, amorphous silicon, polysilicon, or the like.

The etching target layer 110 may be formed by: a deposition process such as a chemical vapor deposition (CVD), a sputtering, an atomic layer deposition (ALD), or the like; a coating process such as a spin coating, a slit coating, or the like; or a printing process such as an inkjet printing, a screen printing, or the like.

The photoresist layer 120 may be formed by coating and curing (e.g., a soft-baking) a photoresist composition including a photosensitive binder resin by the above-mentioned coating process. The photoresist composition may be a negative-type composition or a positive-type composition.

The negative-type composition may include a binder resin that may be photo cured by an exposure light. The positive-type composition may include a photo-active compound (PAC) that may be transformed by the exposure light to become soluble to a developing solution, or a photoacid generator (PAG) that generates an acid by light to increase solubility of a resin.

Hereinafter, embodiments of a method of forming a pattern will be described based on embodiments in which the photoresist layer 120 is formed of the positive-type composition.

Referring to FIG. 4, in an embodiment of a method of forming a pattern, an exposure process may be performed using the photomask 50 described with reference to FIG. 1.

The photomask 50 may be aligned over the photoresist layer 120 in a way such that the light-shielding layer 80 and the second translucent layer 70b of the photomask 50 may face the photoresist layer 120.

Thereafter, a light source LS may be disposed over the first translucent layer 70a and then a light may be radiated. The light source LS may include an ultraviolet light source. In an embodiment, for example, the light source LS may include a light source of G-line, H-line, I-line, ArF, KrF, or the like. In some embodiments, a light source having a wavelength in a range from about 360 nm to about 370 nm, e.g., an I-line light source, may be used.

The light radiated from the light source LS may pass through an opening of the photomask 50 and may be selectively radiated to a partial area of the photoresist layer 120. Accordingly, a portion of the photoresist layer 120 overlapping the opening may be substantially exposed to form an exposed portion 120b. Thus, the photoresist layer 120 may be divided into the exposed portion 120b and a non-exposed portion 120a.

Referring to FIG. 5, the exposed portion 120b may be removed by a developing process using a developing solution. A photoresist pattern 125 may be formed from the non-exposed portion 120a remaining after the developing process. The developing solution may include a basic compound such as an ammonium hydroxide-based compound.

A portion of the light radiated from the light source LS may be reflected by the second translucent layer 70b of the photomask 50, thereby generating a partial reflected light 40. The partial reflected light 40 may be reflected by the first translucent layer 70a having a relatively high reflectivity, thereby generating a re-reflected light 45.

The above-described partial reflected light 40 and the re-reflected light 45 may be repeatedly generated, so that a light resonance may be induced in the photomask 50 or the transparent substrate 60. Accordingly, the re-reflected light 45 may be merged or strengthened through a constructive interference, and an accumulated light 30 may be radiated to the photoresist layer 120 through the opening OP.

As illustrated in FIG. 5, distribution of a light energy may be sharpened and a Gaussian distribution having a narrow width may be formed through the above-described constructive interference and/or resonance effect. Thus, the photoresist pattern 125 having a relatively vertical sidewall profile may be formed while suppressing generation of the inclined portion TP in the non-exposed portion 120a shown in FIG. 2.

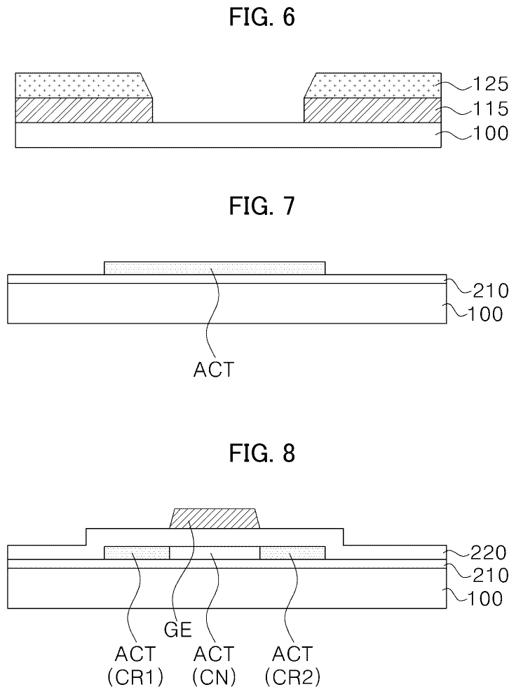

Referring to FIG. 6, the etching target layer 110 may be partially etched using the photoresist pattern 125 as an etching mask. Accordingly, a target pattern 115 may be formed by the remaining etching target layer 110.

In some embodiments, the target pattern 115 may include a hole formed by removing a region of the etching target layer 110 overlapping the exposed portion 120b.

As described above, the photoresist pattern 125 having a desired target threshold dimension CD may be formed using the photomask according to embodiments. The hole or the target pattern 115 having a narrow line width/high resolution may be formed using the photoresist pattern 125.

After the above-described photo-lithography process, the photoresist pattern 125 may be removed through an ashing process and/or a strip process.

FIGS. 7 to 16 are schematic cross-sectional views illustrating a method of manufacturing a display device according to embodiments. Elements and structures of the display device described with reference to FIGS. 7 to 16 are provided as an example, and the use of the photomask 50 and the structure of the display device disclosed in the present application are not limited to those illustrated in FIGS. 7 to 16.

Referring to FIG. 7, in an embodiment of a method of manufacturing a display device, a buffer layer 210 may be formed on the substrate 100. An active layer ACT may be formed on the buffer layer 210.

Moisture penetrating through the substrate 100 may be blocked by the buffer layer 210, and diffusion of impurities between the substrate 100 and structures formed on the substrate 100 may also be blocked by the buffer layer. The buffer layer 210 may entirely cover a top surface of the substrate 100.

The buffer layer 210 may be formed to include an inorganic insulating material such as silicon oxide, silicon nitride, or silicon oxynitride. These may be used alone or in a combination thereof. In some embodiments, the buffer layer 210 may have a stacked structure including a silicon oxide layer and a silicon nitride layer. The buffer layer 210 may be formed by a deposition process such as a CVD process, a sputtering process, or an ALD process to include the above-mentioned inorganic insulating material.

In some embodiments, the buffer layer 210 may include an organic layer, and may be formed in a multi-layered structure of an organic layer and an inorganic layer.

In an embodiment, for example, a semiconductor layer may be formed on the top surface of the buffer layer 210 by a deposition process such as a sputtering process. The semiconductor layer may be patterned to be repeatedly/regularly arranged for each pixel by a photo-lithography process to form the active layer ACT.

In some embodiments, the semiconductor layer may be formed to include a silicon compound such as polysilicon or amorphous silicon. In some embodiments, the semiconductor layer may be formed to include or busing an oxide semiconductor such as indium gallium zinc oxide (IGZO), zinc tin oxide (ZTO), ITZO, or the like.

Referring to FIG. 8, in an embodiment of a method of manufacturing a display device, a gate insulation layer 220 covering an active layer ACT may be formed on the buffer layer 210. A gate electrode GE may be formed on the gate insulation layer 220.

The gate insulation layer 220 may be formed of the above-mentioned inorganic insulating material by the above-mentioned deposition process.

A first conductive layer may be formed on the top surface of the gate insulation layer 220 by the above-mentioned deposition process, and the gate electrode GE may be formed by partially removing the first conductive layer by a photo-lithography process.

In an embodiment, for example, the first conductive layer may include a metal such as Ag, Mg, Al, W, Cu, Ni, Cr, Mo, Ti, Pt, Ta, Nd, Sc, an alloy thereof, or a nitride thereof. In some embodiments, the first conductive layer may be formed in a multi-layered structure (e.g., a Ti layer, an Al layer, and a Ti layer).

Thereafter, a p-type dopant or an n-type dopant may be injected into the active layer ACT by an ion implantation process using the gate electrode GE as an ion implantation mask. Accordingly, a first contact region CR1 and a second contact region CR2 may be formed at one side and the other side of the active layer ACT, respectively. The first contact region CR1 and the second contact region CR2 may correspond to a source region and a drain region, respectively.

A portion of the active layer ACT between the first contact region CR1 and the second contact region CR2 overlapping the gate electrode GE in a vertical direction (or a thickness direction of the substrate 100) may be defined as a channel region CN.

A transistor may be defined by the active layer ACT including the first contact region CR1 and the second contact region CR2, the gate insulation layer 220, and the gate electrode GE. The transistor may be formed as a thin film transistor (TFT) of a display device, and may serve as a pixel driving transistor or a switching transistor.

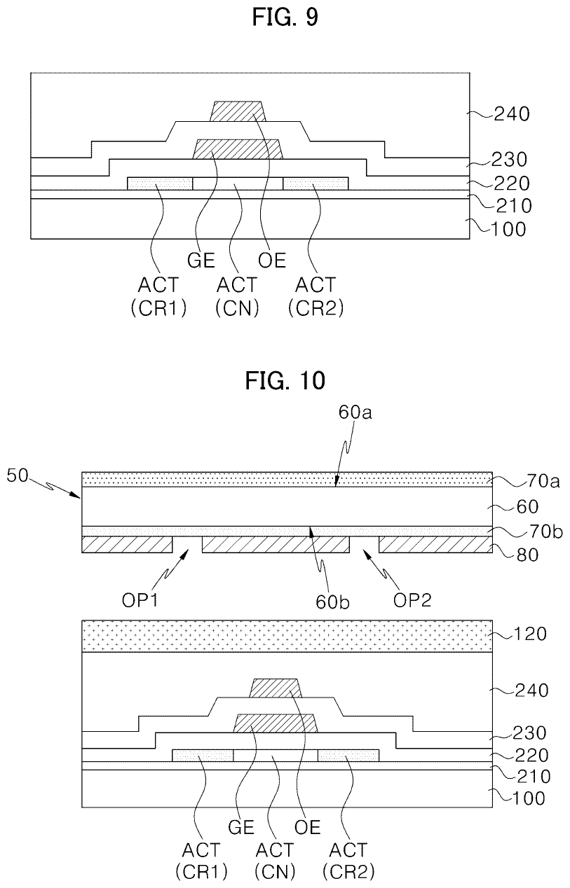

Referring to FIG. 9, in an embodiment of a method of manufacturing a display device, a first insulating interlayer 230 may be formed on the gate insulation layer 220. The first insulating interlayer 230 may be formed of the above-mentioned inorganic insulating material by the above-mentioned deposition process.

A second conductive layer including a metal or alloy substantially the same as or similar to that of the first conductive layer may be formed on the first insulating interlayer 230. An overlapping electrode OE may be formed by partially removing the second conductive layer by a photo-lithography process.

The overlapping electrode OE may overlap the gate electrode GE in the vertical direction. In some embodiments, the overlapping electrode OE may serve as an upper gate. In some embodiments, a storage capacitor may be defined by the gate electrode GE, the first insulating interlayer 230, and the overlapping electrode OE.

A second insulating interlayer 240 covering the overlapping electrode OE may be formed on the first insulating interlayer 230.

In some embodiments, the overlapping electrode OE may be omitted. such embodiments, the first and second insulating interlayers 230 and 240 may be formed as substantially a single insulating interlayer.

Referring to FIG. 10, in an embodiment of a method of manufacturing a display device, a photoresist layer 120 may be formed on the insulating interlayer (e.g., the second insulating interlayer 240).

In this process, as described above, the photomask 50 according to embodiments may be disposed over the photoresist layer 120. The photomask 50 may be disposed over the photoresist layer 120 such that the light-shielding layer 80 and the second translucent layer 70b may face the photoresist layer 120.

The light-shielding layer 80 may be provided with a first opening OP1 and a second opening OP2. The second translucent layer 70b may be exposed through the first opening OP1 and the second opening OP2.

According to embodiments, the photomask 50 may be aligned in a way such that the first opening OP1 and the second opening OP2 may overlap the first contact region CR1 and the second contact region CR2 of the active layer ACT in the vertical direction, respectively.

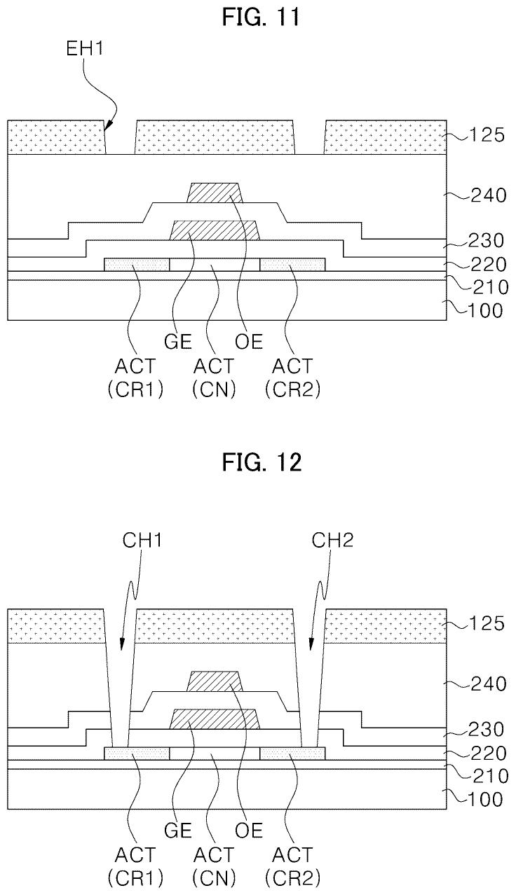

Referring to FIG. 11, in an embodiment of a method of manufacturing a display device, a photoresist pattern 125 may be formed by partially removing the photoresist layer 120 by a photo-lithography process including substantially the same exposure and development process as those described with reference to FIGS. 4 and 5.

A portion of the photoresist layer 120 that may overlap the first and second openings OP1 and OP2 of the photomask 50 may be converted into an exposed portion, and then the exposed portion may be removed by the developing process to form the photoresist pattern 125. The photoresist pattern 125 may be provided with a first etching hole EH1 formed in a space from which the exposed portion is removed.

Referring to FIG. 12, in an embodiment of a method of manufacturing a display device, contact holes CH1 and CH2 may be formed by partially etching the insulating interlayers 230 and 240 and the gate insulation layer 220 by an etching process using the photoresist pattern 125 as an etching mask.

In some embodiments, the contact holes CH1 and CH2 may be formed a dry etching process by injecting an etching gas through the first etching hole EH1.

The contact holes may include a first contact hole CH1 and a second contact hole CH2 exposing the first contact region CR1 and the second contact region CR2 of the active layer ACT, respectively.

In an embodiment of a method of manufacturing a display device, as described above, the first etching hole EH1 having a narrow line width and a steep sidewall may be formed by the construction interference and/or the light resonance effect of the photomask 50 according to embodiments of the present disclosure. Thus, the contact holes CH1 and CH2 having a high aspect ratio may be effectively formed.

After the formation of the contact holes CH1 and CH2, the photoresist pattern 125 may be removed by an ashing process and/or a strip process.

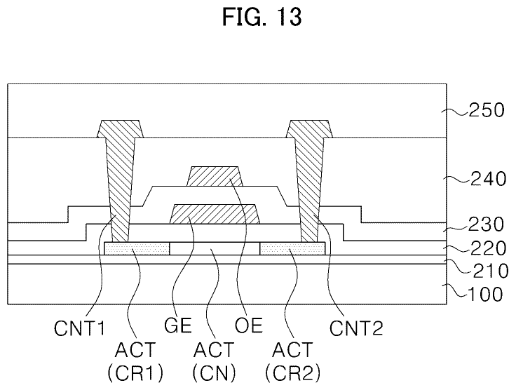

Referring to FIG. 13, in an embodiment of a method of manufacturing a display device, a first contact electrode CNT1 and a second contact electrode CNT2 which may be in contact with or electrically connected to the first contact region CR1 and the second contact region CR2, respectively, through the first contact hole CH1 and the second contact hole CH2 may be formed.

In an embodiment, for example, a third conductive layer filling the contact holes CH1 and CH2 may be formed on the second insulating interlayer 240. The third conductive layer may be formed by a deposition process such as a sputtering process to include a metal or an alloy substantially the same as or similar to that of the first conductive layer or the second conductive layer. Thereafter, a portion of the third conductive layer formed on the top surface of the second insulating interlayer 240 may be patterned by a photo-lithography process to form the first contact electrode CNT1 and the second contact electrode CNT2.

The first contact electrode CNT1 and the second contact electrode CNT2 may serve as a source electrode and a drain electrode, respectively.

A via insulation layer 250 covering the first contact electrode CNT1 and the second contact electrode CNT2 may be formed on the second insulating interlayer 240. The via insulation layer 250 may be formed by a coating process such as a spin coating process to include an organic material such as polyimide, an epoxy resin, an acrylic resin, polyester, a siloxane resin, benzocyclobutene (BCB), or the like. The via insulation layer 250 may serve as a planarization layer.

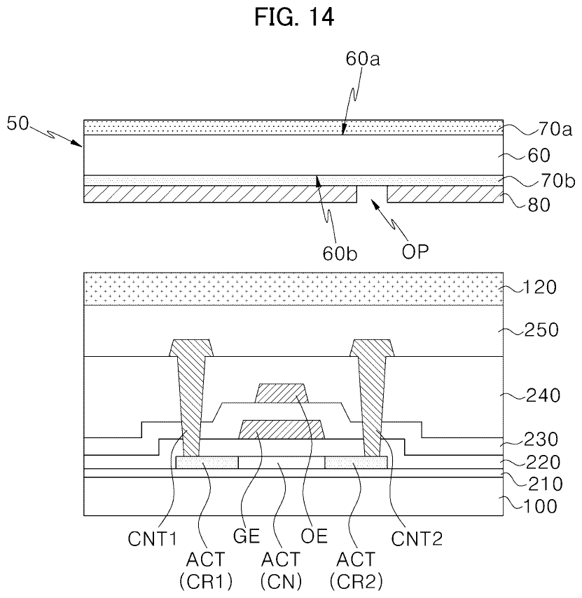

Referring to FIG. 14, in an embodiment of a method of manufacturing a display device, a photoresist layer 120 may be formed on the via insulation layer 250. In this process, the photomask 50 according to embodiments as described above may be disposed on the photoresist layer 120. The photomask 50 may be disposed on the photoresist layer 120 such that the light-shielding layer 80 and the second translucent layer 70b may face the photoresist layer 120. The light-shielding layer 80 may include an opening OP. The second translucent layer 70b may be exposed through the opening OP.

According to embodiments, the photomask 50 may be aligned in a way such that the opening OP may overlap a top surface of the contact electrode (e.g., the second contact electrode CNT2).

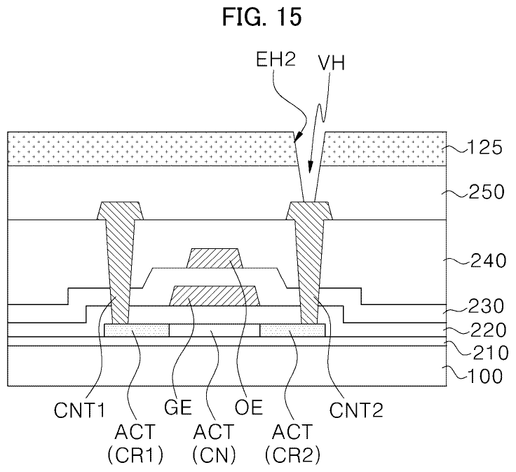

Referring to FIG. 15, in an embodiment of a method of manufacturing a display device, the photoresist layer 120 may be partially removed by a photo-lithography process including substantially the same exposure and development processes as described with reference to FIGS. 4 and 5 to form a photoresist pattern 125.

A portion of the photoresist layer 120 which may overlap the opening OP of the photomask 50 may be converted into an exposed portion, and then the exposed portion may be removed by a developing process to form the photoresist pattern 125. The photoresist pattern 125 may include a second etching hole EH1 formed in a space from which the exposed portion is removed.

A via hole VH may be formed by partially etching the via insulation layer 250 by an etching process using the photoresist pattern 125 as an etching mask. The top surface of the second contact electrode CNT2 may be exposed through the via hole VH.

In some embodiments, the via hole VH may be formed by a dry etching process by injecting an etching gas through the second etching hole EH2.

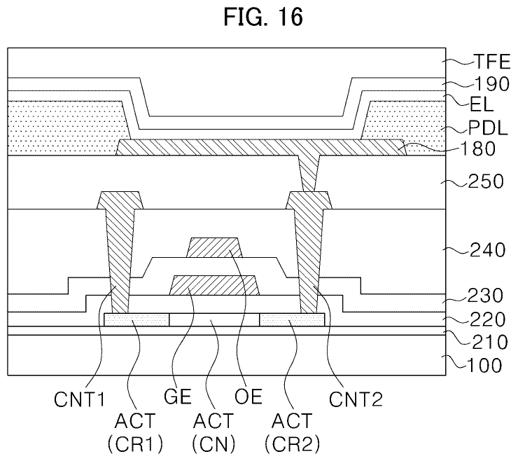

Referring to FIG. 16, in an embodiment of a method of manufacturing a display device, a first electrode 180 filling the via hole VH may be formed on the via insulation layer 250. The first electrode 180 may include a via electrode, and may include a pixel electrode of a light-emitting device as will be described later.

In some embodiments, the first electrode 180 includes a plurality of via electrodes, and an uppermost via electrode among the via electrodes may serve as the pixel electrode.

In an embodiment, for example, a fourth conductive layer filling the via hole VH may be formed on a top surface of the via insulation layer 250. The first electrode 180 may be formed by partially removing the fourth conductive layer on the top surface of the via insulation layer 250 by a photo-lithography process.

The first electrode 180 may serve as a pixel electrode or an anode, and may include a high work function conductive material that may promote hole injection. The first electrode 180 may be formed as a transmissive electrode. The fourth conductive layer or the first electrode 180 may be formed to include a transparent conductive oxide such as indium tin oxide (ITO), indium zinc oxide (IZO), indium tin oxide (ZnO), and indium tin oxide(ITZO) .

The first electrode 180 may be formed as a translucent electrode or a reflective electrode. The fourth conductive layer or the first electrode 180 may be formed to include at least one metal selected from Ag, Mg, Cu, Al, Pt, Pd, Au, Ni, Nd, Ir, Cr, Li, Ca, LiF, Mo, Ti, W, In, Sn, Zn, or the like, or an alloy thereof.

The fourth conductive layer or the first electrode 180 may be formed in a single-layered structure or a multi-layered structure. In an embodiment, for example, the first electrode 180 may have a triple-layered structure of ITO/Ag/ITO.

A pixel defining layer PDL may be formed on the via insulation layer 250 to at least partially expose a top surface of the first electrode 180. The pixel defining layer PDL may cover a peripheral portion of the first electrode 180.

A light-emitting region may be defined by a sidewall of the pixel defining layer PDL. In an embodiment, for example, a green light-emitting region, a blue light-emitting region, and a red light-emitting region may be separated and defined by the pixel defining layer PDL.

The pixel defining layer PDL may be formed using, e.g., an organic material such as a polysiloxane resin, a polyimide resin, an acrylic resin, or the like. The pixel defining layer PDL may include a colorant material such as a black pigment/dye dispersed in the resin material.

A light-emitting portion EL may be formed on the first electrode 180 and the pixel defining layer PDL. The light emitting portion EL may include an organic light-emitting layer that may be independently patterned for each of a red pixel, a green pixel and a blue pixel to generate lights of different colors for each of the pixels.

In an embodiment, the light-emitting portion EL may continuously and commonly extend throughout a plurality of pixels. In such an embodiment, the light-emitting portion EL may include a white emission layer or a blue emission layer. In an embodiment, the light-emitting portion EL may include emission layers corresponding to lights of a plurality of different colors, and may include a tandem stack structure.

In an embodiment, for example, the light-emitting portion EL may be formed by a process such as a thermal deposition, a vapor deposition, a vacuum deposition, a spin coating, an inkjet printing, a laser printing, a casting, a laser thermal transfer, or the like.

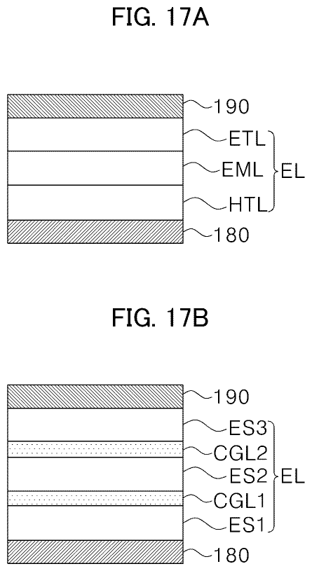

The light-emitting device including the light-emitting portion EL will be described in more detail with reference to FIGS. 17A and 17B.

The second electrode 190 may be formed on the light-emitting portion EL. The second electrode 190 may be a common electrode that may be continuously provided in a plurality of light-emitting regions or pixels.

The second electrode 190 may serve as an electron injection electrode or a cathode. The second electrode 190 may include a metal, an alloy, an electrically conductive compound, or the like, having a low work function.

In an embodiment, for example, the second electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These may be used alone or in a combination thereof.

The second electrode 190 may be formed as a transmissive electrode, a translucent electrode, or a reflective electrode. The second electrode 190 may have a single-layered structure or a multi-layered structure.

The light-emitting device may be defined by the first electrode 180, the light-emitting portion EL, and the second electrode 190 as described above. The light-emitting device may be provided as an organic light-emitting diode (OLED) device.

An encapsulation layer TFE may be formed on the second electrode 190. The encapsulation layer TFE may be disposed on the pixel defining layer PDL and the light-emitting devices to protect the light-emitting devices from moisture or oxygen.

The encapsulation layer TFE may include at least one selected from:
inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)), or any combination thereof; or a combination of the inorganic and organic layers.

The encapsulation layer TFE may be formed in a single-layered or a multi-layered structure. In some embodiments, the encapsulation layer TFE may have a sequential stacked structure of a first inorganic layer, an organic layer, and a second inorganic layer.

In some embodiments, a color control layer overlapping the light-emitting portion EL may be disposed on the encapsulation layer TFE. The color control layer may include a color conversion layer including quantum dots and/or a color filter.

According to the above-described embodiments, a contact hole or a via hole for forming a contact electrode or a via electrode may be formed using the photomask 50 according to embodiments of the present disclosure. Accordingly, a hole for forming a wiring/electrode having a fine line width may be formed to have desired resolution and reliability.

The use or application of the photo-lithography process using the photomask 50 according to embodiments of the present disclosure is not limited to the hole forming process. In an embodiment, for example, the photomask 50 according to embodiments of the present disclosure may be used in the photo-lithography process of the semiconductor layer for forming the active layer ACT, and/or the photo-lithography process of the first to fourth conductive layers for forming the gate electrode GE, the overlapping electrode OE, the contact electrodes CNT and CNT2 and/or the first electrode 180.

FIGS. 17A and 17B are schematic cross-sectional views illustrating light emitting devices included in a display device according to embodiments.

Referring to FIG. 17A, in an embodiment, the light-emitting device may include the first electrode 180, the second electrode 190, and the light-emitting portion EL disposed between the first electrode 180 and the second electrode 190 as described above.

The light-emitting portion EL may include a hole transport layer HTL, an emission layer EML and an electron transport layer ETL. According to embodiments, the hole transport layer HTL, the emission layer EML, the electron transport layer ETL and the second electrode 190 may be sequentially stacked from a top surface of the first electrode 180.

The emission layer EML may include an organic light-emitting material having red, green or blue emission properties. In an embodiment, for example, the emission layer EML may include a fluorescent host and/or a host for a phosphorescent light-emitting device, and may further include a fluorescent dopant, a phosphorescent dopant, and/or a thermally activated delayed fluorescence (TADF) dopant.

In an embodiment, for example, the hole transport layer HTL may include a hole transporting material such as m-MTDATA (4,4′,4″-[tris(3-methylphenyl)phenylamino] triphenylamine), TDATA (4,4′4″-tris(N, N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

In an embodiment, for example, the electron transport layer ETL may include an electron transporting material such as an anthracene-based compound, Alq₃ (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In some embodiments, a hole injection layer may be further disposed between the first electrode 180 and the hole transport layer HTL. An electron injection layer may be further disposed between the second electrode 190 and the electron transport layer ETL.

In some embodiments, the hole transport layer HTL and the electron transport layer ETL may be formed as a common layer continuously extending across a plurality of pixels. The emission layer EML may be independently patterned for individual pixels of different colors.

Referring to FIG. 17B, in another embodiment, the light-emitting portion EL may include a plurality of light-emitting structures ES1, ES2 and ES3. Each of the light-emitting structures ES1, ES2 and ES3 may include the hole transport layer, the emission layer and the electron transport layer. According to embodiments, the light-emitting device of FIG. 17B may be a light-emitting device having a tandem structure that may generate a white light or a blue light.

Charge generation layers CGL1 and CGL2 may be disposed between neighboring light-emitting structures ES1, ES2 and ES3. The charge generation layers CGL1 and CGL2 may include a p-type charge generation layer and/or an n-type charge generation layer. The charge generation layers CGL1 and CGL2 may include a first charge generation layer CGL1 disposed between the first light-emitting structure ES1 and the second light-emitting structure ES2, and a second charge generation layer CGL2 disposed between the second light-emitting structure ES2 and the third light-emitting structure ES3.

According to embodiments, the first light-emitting structure ES1, the first charge generation layer CGL1, the second light-emitting structure ES2, the second charge generation layer CGL2, the third light-emitting structure ES3, and the second electrode 190 may be sequentially stacked from the top surface of the first electrode 180.

The light-emitting portion EL included in the light-emitting device may be provided as a common layer for a plurality of pixels. In some embodiments, a blue light or a white light may be emitted from the light-emitting portion EL, and a color for each pixel may be implemented by the above-described color control layer.

Although FIG. 17B illustrates an embodiment where the light-emitting device has a triple-layered tandem structure, the light-emitting device may have a tandem structure having two, or four or more of the light-emitting structure in another embodiment.

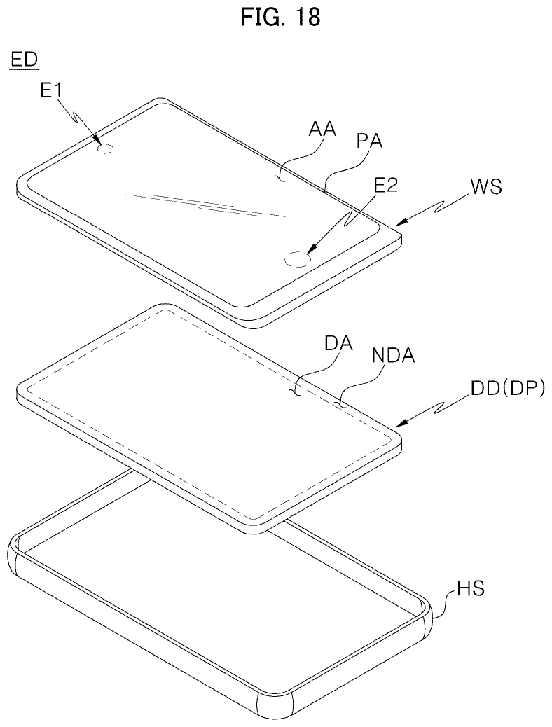

FIG. 18 is an exploded perspective view of an electronic device according to embodiments.

According to embodiments, an electronic device ED may be implemented in the form of a mobile phone (smart phone), a tablet computer, a personal computer (PC), or the like, including the above-described display device that may include a structure formed by the photo-lithography process using the above-described photomask 50.

Referring to FIG. 18, an embodiment of the electronic device ED may include a window structure WS, a display panel DD, and a housing HS. The display device DD may include a display panel DP including the transistors and the light-emitting devices as described above. The housing HS, the display device DD, and the window structure WS may be sequentially stacked along the third direction.

The window structure WS may provide an external display surface recognized by a user, such as a viewing surface of a mobile phone, and may include a transparent material film. In an embodiment, for example, the window structure WS may include glass (e.g., ultra-thin glass (UTG)), a hard coating film, a plastic film, or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the electronic device ED.

The display device DD or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In some embodiments, functional device areas E1 and E2 may be included in the active area AA of the window structure WS. In an embodiment, for example, a first functional device area E1 may be included at one end portion of the active area AA and may be implemented, e.g., in the form of a camera hole. The second functional device area E2 may serve as a fingerprint sensing area.

In an embodiment, for example, a sensor structure for a touch sensing or a fingerprint sensing may be disposed in the display panel DP or between the window structure WS and the display panel DP.

The housing HS may serve as a frame structure or a rear housing of the display device DD or the electronic device ED. A cover panel may be disposed between the housing HS and the display panel DP. The housing HS or the cover panel may include a plate (e.g., an SUS plate) that supports the display panel DP. The housing HS or the cover panel may include an elastic body for absorbing shock of the display device DD.

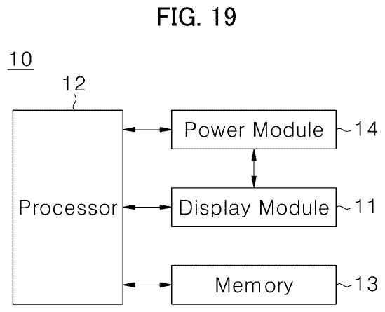

FIG. 19 is a block diagram of an electronic device according to an embodiment.

Referring to FIG. 19, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power used for the operation of the electronic device 10.

At least one of components of the electronic device 10 as described above may be included in the display device according to the above-described embodiments. Additionally, some of individual modules functionally included in one module may be included in the display device, and others may be provided separately from the display device. In an embodiment, for example, the display module 11 may include the display device, and the processor 12, the memory 13 and the power module 14 may be provided in the form of another device in the electronic device 10 different from the display device.

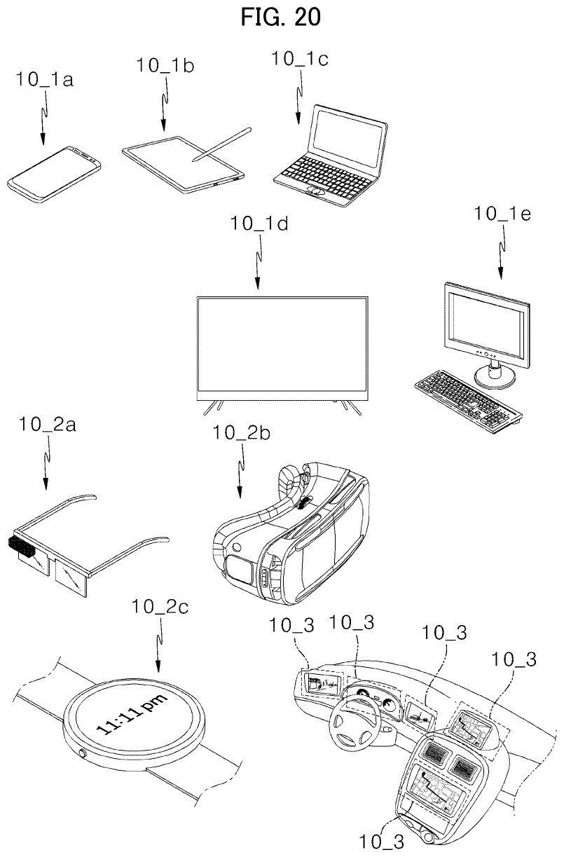

FIG. 20 is a schematic diagrams of electronic devices according to embodiments.

Referring to FIG. 20, non-limiting examples of various electronic devices to which the display device according to the above-described embodiments is applied include an electronic device for displaying an image such as a smartphone 10_1a, a tablet PC 10_1b, a laptop computer 10_1c, a television (TV) 10_1d, a desk monitor 10_1e, or the like; a wearable electronic device including a display module such as smart glasses 10_2a, a head mounted display 10_2b, a smart watch 10_2c, or the like; a vehicle electronic device 10_3 including a display module such as a center information display (CID) disposed at a vehicle instrument panel, a center fascia, a dashboard, etc., a head-up display, a room mirror display, or the like. The electronic device may include a virtual reality glass or an augmented reality glass.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A photomask, comprising:
a transparent substrate having a first surface and a second surface, which are opposite to each other;
a first translucent layer disposed on the first surface of the transparent substrate;
a light-shielding layer disposed on the second surface of the transparent substrate; and
a second translucent layer disposed between the second surface of the transparent substrate and the light-shielding layer,
wherein the second translucent layer has a higher transmittance than a transmittance of the first translucent layer.

2. The photomask of claim 1, wherein the first translucent layer has a higher reflectance than a reflectance of the second translucent layer.

3. The photomask of claim 1, wherein each of the first translucent layer and the second translucent layer include a metal, a metal oxide, or an organic material.

4. The photomask of claim 3, wherein
the light-shielding layer includes a first metal, and
the first translucent layer or the second translucent layer includes a second metal different from the first metal.

5. The photomask of claim 4, wherein
the first metal includes chromium (Cr) or molybdenum (Mo), and
the second metal includes aluminum (Al), silver (Ag), copper (Cu), or tungsten (W).

6. The photomask of claim 5, wherein the second metal includes aluminum (Al) or silver (Ag).

7. The photomask of claim 3, wherein
the first translucent layer includes the metal or the metal oxide, and
the second translucent layer includes the organic material.

8. The photomask of claim 1, wherein a thickness of the first translucent layer is greater than a thickness of the second translucent layer.

9. The photomask of claim 8, wherein
the thickness of the first translucent layer is in a range from about 5 nm to about 20 nm, and
the thickness of the second translucent layer is in a range from about 1 nm to about nm.

10. The photomask of claim 8, wherein the first translucent layer and the second translucent layer include the same metal as each other.

11. The photomask of claim 1, wherein a thickness of each of the first translucent layer and the second translucent layer is less than a thickness of the light-shielding layer.

12. The photomask of claim 1, wherein
an opening is defined through the light-shielding layer, and
the second translucent layer is exposed through the opening of the light-shielding layer.

13. A method for forming a pattern, the method comprising:
forming an etching target layer on a substrate;
forming a photoresist layer on the etching target layer;
arranging a photomask on the photoresist layer;
forming a photoresist pattern by partially removing the photoresist layer by an exposure process using the photomask and a development process; and
partially etching the etching target layer using the photoresist pattern,
wherein the photomask comprises:
a transparent substrate having a first surface and a second surface, which are opposite to each other;
a first translucent layer disposed on the first surface of the transparent substrate;
a light-shielding layer disposed on the second surface of the transparent substrate; and
a second translucent layer disposed between the second surface of the transparent substrate and the light-shielding layer,
wherein the second translucent layer has a higher transmittance than a transmittance of the first translucent layer.

14. The method of claim 13, wherein the exposure process using the photomask is performed by generating a constructive interference or an optical resonance of a light radiated from a light source between the first translucent layer and the second translucent layer of the photomask.

15. The method of claim 14, wherein the constructive interference or the optical resonance is generated by repeatedly generating a partial reflected light of light radiated from the light source by the second translucent layer and a re-reflected light by the first translucent layer.

16. A method of manufacturing a display device, the method comprising:
forming a transistor including an active layer on a substrate;
forming an insulating interlayer covering the transistor;
forming a contact electrode penetrating the insulating interlayer and electrically connected to the active layer;
forming a via insulation layer covering the contact electrode on the insulating interlayer;
forming a via electrode penetrating the via insulation layer and electrically connected to the contact electrode; and
forming a light-emitting device electrically connected to the transistor through the via electrode or the contact electrode,
wherein the forming the contact electrode or the forming the via electrode comprises performing a photo-lithography process using a photomask,
wherein the photomask comprises:
a transparent substrate having a first surface and a second surface, which are opposite to each other;
a first translucent layer disposed on the first surface of the transparent substrate;
a light-shielding layer disposed on the second surface of the transparent substrate; and
a second translucent layer disposed between the second surface of the transparent substrate and the light-shielding layer,
wherein the second translucent layer has a higher transmittance than a transmittance of the first translucent layer.

17. The method of claim 16, wherein the forming the contact electrode comprises:
forming a photoresist layer on the insulating interlayer;
arranging the photomask on the photoresist layer;
forming a photoresist pattern including a first etching hole by partially removing the photoresist layer by an exposure process using the photomask and a development process;
partially etching the insulating interlayer using the first etching hole of the photoresist pattern to form a contact hole exposing a portion of the active layer; and
forming a conductive layer filling the contact hole.

18. The method of claim 16, wherein the forming the via electrode comprises:
forming a photoresist layer on the via insulation layer;
arranging the photomask on the photoresist layer;
forming a photoresist pattern including a second etching hole by partially removing the photoresist layer by an exposure process using the photomask and a development process;
partially etching the via insulation layer using the second etching hole of the photoresist pattern to form a via hole exposing a portion of the contact electrode; and
forming a conductive layer filling the via hole.

19. An electronic device comprising:
the display device manufactured by the method of claim 16;
a memory; and
a processor which executes data included in the memory to control an operation of the display device.

20. The electronic device of claim 19, wherein the electronic device includes virtual reality or augmented reality glasses, a smartphone, a tablet PC, a laptop computer, a TV, a desk monitor, smart glasses, a head-mounted display, a smart watch, or a vehicle display.
